(19) United States
(12) Patent Application Publication
(10) Pub. No.: US 2013/0088660 A1
(43) Pub. Date: Apr. 11, 2013

(54) THIN FILM TRANSISTOR SUBSTRATE AND LIQUID CRYSTAL DISPLAY DEVICE

(71) Applicant: Seiji Kaneko, Osaka (JP)

(72) Inventor: Seiji Kaneko, Osaka (JP)

(73) Assignee: SHARP KABUSHIKI KAISHA, Osaka (JP)

(21) Appl. No.: 13/703,783

(22) PCT Filed: Apr. 26, 2011
(86) PCT No.: PCT/JP2011/002437

§ 371 Date: Dec. 12, 2012

(30) Foreign Application Priority Data
Jun. 15, 2010 (JP) 2010-135877

(51) Int. Cl. H01L 27/15

(52) U.S. Cl. CPC H01L 27/15
USPC 349/43; 257/59; 257/72

(57) ABSTRACT

Disclosed is a liquid crystal display device including a thin film transistor substrate, in which changes in the potential at a pixel electrode can be suppressed without decreasing the aperture ratio of a pixel. Gate wiring lines and source wiring lines are covered with a multilayer insulating film made of two layers of interlayer insulating films that overlap each other. Pixel electrodes are formed on the multilayer insulating film, and a shield electrode, which is formed of a transparent conductive material, is provided between the two layers of interlayer insulating films so as to extend along the gate wiring lines and the source wiring lines and to lie between the gate electrodes or the source electrodes and the pixel electrodes.

### TECHNICAL FIELD

The present invention relates to a thin film transistor (referred to as a TFT below) substrate and to a liquid crystal display device provided with the same, and more particularly, to a countermeasure against fluctuations in the screen brightness, i.e., flickering, to achieve a reduction in power consumption by low-frequency driving.

### BACKGROUND ART

An active matrix driving type liquid crystal display device has a structure in which a liquid crystal layer is sealed between a TFT substrate and an opposite substrate facing each other, and by having TFTs in respective pixels, each of which is the smallest unit of an image, the liquid crystal display device can display high-resolution images.

The TFT substrate includes a plurality of gate wiring lines that extend in parallel with each other, a plurality of source wiring lines that extend in parallel with each other so as to intersect with the respective gate wiring lines, and TFTs and pixel electrodes that are respectively provided for intersections of the respective gate wiring lines and the respective source wiring lines. A plurality of pixels, each of which includes a TFT and a pixel electrode, are defined by the respective gate wiring lines and the respective source wiring lines. In this TFT substrate, an interlayer insulating film is formed so as to cover the respective TFTs, and a plurality of pixel electrodes are arranged in a matrix on the interlayer insulating film so as to correspond to the respective pixels. The plurality of pixel electrodes are respectively connected to the TFTs through contact holes that are formed in the interlayer insulating film. The opposite substrate is provided with a common electrode that faces the respective pixel electrodes.

A transmissive liquid crystal display device, for example, is configured such that source signal voltages are supplied from the source wiring lines to the respective pixel electrodes line-sequentially through TFTs that are selected by driving the gate wiring lines, and by controlling the size of the voltages applied to the liquid crystal layer between the respective pixel electrodes and the common electrode, the orientation state of liquid crystal molecules are changed, allowing the transmittance of light from a backlight, which is disposed on the rear surface side, to be adjusted in each pixel. This way, the liquid crystal display device can display images.

In the TFT substrate, a structure in which outer edges of each pixel electrode overlap the gate wiring lines and the source wiring lines through the interlayer insulating film is widely adopted in order to maximize the area of each pixel electrode. In the TFT substrate having such a structure, a parasitic capacitance is formed between the gate wiring lines or the source wiring lines and the pixel electrodes due to a potential difference therebetween, and therefore, the potential at the pixel electrodes changes in accordance with the permittivity of the interlayer insulating film disposed between these wiring lines and the pixel electrode, causing fluctuations of the screen brightness, i.e., flickering.

To solve this problem, a technique for reducing the parasitic capacitance between the pixel electrodes and the source wiring lines in order to suppress the potential change at the pixel electrodes has been proposed. In Patent Document 1, for example, a shielding electrode that is made of the same film as that forming the gate wiring lines is disposed above each source wiring line through the gate insulating film, making it possible to achieve an excellent display quality.

### RELATED ART DOCUMENT

### Patent Document

Patent Document 1: Japanese Patent Application Laid-Open Publication No. H10-39336

### SUMMARY OF THE INVENTION

### Problems to be Solved by the Invention

However, as described in Patent Document 1, when the shielding electrode is made of the same film as that forming the gate wiring lines, the shielding electrode is formed in the same layer as the gate wiring lines, and therefore, the shielding electrode cannot prevent the potential change at the pixel electrodes that is caused by a parasitic capacitance between the pixel electrodes and the gate wiring lines. As a result, there is still a possibility of causing the flickering, which is recognized as display anomaly. Typical gate wiring lines are often made of a metal material that has a light-shielding property, and therefore, the shielding electrode also has a light-shielding property, and regions where the shielding electrode is formed become non-transmissive regions. In such a case, if the shielding electrode is made wider than the source wiring lines so as to prevent a parasitic capacitance from being formed as a result of fringe fields, for example, the aperture ratio of the pixels would be lowered. The lower aperture ratio of the pixels directly causes an increase in power consumption of the backlight in the transmissive liquid crystal display device to ensure the screen brightness, and should therefore be avoided from the perspective of reducing power consumption.

In liquid crystal display devices, in order to reduce the power consumption, a technique of performing so-called low-frequency driving, in addition to a normal operation mode, has been proposed. While the normal operation mode constantly repeats a writing operation for the pixel electrodes at a high frequency, in the low-frequency driving, the display state of a still image is maintained by performing the writing operation at a minimum refresh rate. When such low-frequency driving is performed, however, the above-mentioned display anomaly (flickering) becomes more noticeable.

The present invention was made in view of such problems, and aims at minimizing potential changes at the pixel electrodes without decreasing the aperture ratio of the pixels, and achieving a reduction in power consumption while ensuring a desired display quality.

### Means for Solving the Problems

In order to achieve the above-mentioned objects, in the present invention, a shielding electrode that is made of a transparent conductive material is formed in a different layer from a gate wiring line and a source wiring line so as to extend along the two wiring lines.

Specifically, the present invention is applied to a TFT substrate and a liquid crystal display device equipped with the same, the TFT substrate including: a plurality of gate wiring lines that extend in parallel with each other; a plurality of source wiring lines that extend in parallel with each other so as to intersect with the respective gate wiring lines; and a thin film transistor and a pixel electrode that are disposed for each of intersections of the respective gate wiring lines and the respective source wiring lines, wherein a plurality of pixels, each of which includes the thin film transistor and the pixel electrode, are defined by the respective gate wiring lines and the respective source wiring lines, wherein, in each of the pixels, the thin film transistor includes: a gate electrode; a semiconductor layer; a source electrode; and a drain electrode, the gate electrode being connected to one of the gate wiring lines, which runs through a corresponding intersection, the semiconductor layer overlapping the gate electrode through a gate insulating film, the source electrode being connected to one side of the semiconductor layer and being connected to one of the source wiring lines, which runs through the corresponding intersection, the drain electrode being connected to another side of the semiconductor layer so as to face the source electrode and being connected to the pixel electrode. To solve the above-mentioned problems, the TFT substrate and the liquid crystal display device according to the present invention may be configured as follows.

That is, in a first aspect of the present invention, the TFT substrate is provided with: a multi-layer insulating film that includes two layers of interlayer insulating films laminated to each other and that covers the respective gate wiring lines and the respective source wiring lines, the multi-layer insulating film having the respective pixel electrodes formed thereon; and a shielding electrode that is disposed between the two layers of interlayer insulating films and that is extended along the respective gate wiring lines and the source wiring lines so as to lie between the respective gate wiring lines or the respective source wiring lines and the respective pixel electrodes, the shielding electrode being made of a transparent conductive material.

With this configuration, because the shielding electrode is disposed so as to lie between the respective gate wiring lines or the respective source wiring lines and the respective pixel electrodes, an electric field effect, which is generated as a result of a potential difference between the respective gate wiring lines or the respective source wiring lines and the respective pixel electrodes, is electrically shielded. This makes it possible to reduce or prevent a parasitic capacitance formed therebetween. That is, not only the parasitic capacitance between the pixel electrodes and the source wiring lines, but also the parasitic capacitance between the pixel electrodes and the gate wiring lines is reduced or eliminated, and therefore, potential changes at the pixel electrodes can be minimized. Because the shielding electrode is made of a transparent conductive material, even though the shielding electrode is formed in the respective pixels, the aperture ratio is not lowered. Also, because the shielding electrode is formed so as to extend along the respective gate wiring lines and the respective source wiring lines and to have openings in the respective pixels, the reduction in light transmittance can be prevented.

A second aspect of the present invention is the TFT substrate of the first aspect of the present invention, wherein the shielding electrode is formed wider than the respective gate wiring lines and the respective source wiring lines so as to entirely overlap the respective gate wiring lines and the respective source wiring lines in an width direction thereof.

With this configuration, because the shielding electrode is formed so as to entirely cover the respective gate wiring lines and the respective source wiring lines, it is possible to reduce or prevent the parasitic capacitance formed between the respective gate wiring lines or the respective source wiring lines and the respective pixel electrodes as a result of fringe fields, thereby further suppressing the potential change at the pixel electrodes.

A third aspect of the present invention is the TFT substrate of the first or second aspect of the present invention, wherein the shielding electrode is formed so as to overlap outer edges of the respective pixel electrodes through the interlayer insulating film of an upper layer.

With this configuration, a storage capacitance is formed between the shielding electrode and an outer edge of each pixel electrode that overlaps the shielding electrode, and by this storage capacitance, the potential at each pixel electrode can be maintained during the OFF period of the TFT. This makes it possible to further suppress the potential change at the pixel electrodes.

A fourth aspect of the present invention is the TFT substrate of any one of the first to third aspects of the present invention, wherein the shielding electrode is formed so as to cover the respective TFTs.

With this configuration, the shielding electrode serves as a protective film of each TFT, and because the shielding electrode prevents moisture, oxygen, and the like from entering the TFTs from the outside, the degradation of performance of the TFTs can be prevented.

A fifth aspect of the present invention is the TFT substrate of any one of the first to fourth aspects of the present invention, wherein, of the two layers of interlayer insulating films, at least the interlayer insulating film of the upper layer is made of an organic insulating film or a multi-layer film formed by laminating an inorganic insulating film and an organic insulating film in this order.

With this configuration, the uppermost layer of the multi-layer insulating film is made of an organic insulating film. The organic insulating film can be formed thick with ease by a coating method, and an excellent surface flatness can be achieved. Therefore, the surface of this multi-layer insulating film can have a higher degree of flatness as compared with a multi-layer insulating film having the uppermost layer formed of an inorganic insulating film. This allows the pixel electrodes formed on the multi-layer insulating film to be appropriately planarized, and therefore, the thickness of the liquid crystal layer is made even throughout the respective pixels. As a result, the display quality of the liquid crystal display device is improved. Particularly, when each interlayer insulating film is made of an organic insulating film only, the film formation can be made easier because less film forming processes are required, as compared with the case in which at least one of the interlayer insulating films is made of a multi-layer film. The interlayer insulating films made of organic insulating films tend to allow electric current to flow at high temperatures, and depending on the usage environment, the insulating property thereof may not be maintained, and a small leak current may flow therein. However, in the present invention, because the shielding electrode is formed so as to cover the TFTs, a transfer of electric charges to the upper part of each TFT, which is caused by the leak current, can be blocked by the shielding electrode. This prevents a reliability problem caused by a change in the TFT characteristics that occurs as a result of accumulation of electric charges in the upper part of the TFT, thereby achieving the TFTs having excellent characteristics.

A sixth aspect of the present invention is the TFT substrate of any one of the first to fifth aspects of the present invention, wherein the semiconductor layer of each of the thin film transistors is made of an oxide semiconductor.

With this configuration, each TFT has excellent characteristics of high mobility, high reliability, and low OFF current, which makes it possible to further suppress the potential change at the pixel electrodes.

A seventh aspect of the present invention is the TFT substrate of any one of the first to sixth aspects of the present invention, wherein each of the TFTs has a bottom-gate structure in which the gate electrode is covered by the gate insulating film, and the semiconductor layer, the source electrode, and the drain electrode are formed on the gate insulating film, wherein the TFT substrate further includes: storage capacitance wiring lines that are provided for the respective gate wiring lines, the storage capacitance wiring lines being extended in parallel with each other along the respective gate wiring lines; and storage capacitance elements provided in the respective pixels, and wherein, in each of the pixels, the storage capacitance element includes: a lower electrode that is connected to the storage capacitance wiring line and that is covered by the gate insulating film; a dielectric layer that is made of a portion of the gate insulating film corresponding to the lower electrode; and an upper electrode that is extended from the drain electrode and that overlaps the lower electrode through the dielectric layer.

With this configuration, by the storage capacitance formed in each storage capacitance element, the potential at the pixel electrode can be maintained during the OFF period of the TFT, and therefore, it is possible to further suppress the potential change at the pixel electrode. Because the dielectric layer of the storage capacitance element is made of the gate insulating film, which is relatively thin, it is possible to form the storage capacitance element having a desired capacitance with a smaller area, as compared with the case of making the dielectric layer of a relatively thick insulating film, i.e., an interlayer insulating film. This allows for an improvement in the aperture ratio of the pixels that are respectively provided with the storage capacitance elements.

An eighth aspect of the present invention is a liquid crystal display device that includes: the TFT substrate according to any one of the first to seventh aspects of the present invention; an opposite substrate disposed to face the TFT substrate; and a liquid crystal layer disposed between the TFT substrate and the opposite substrate.

With this configuration, the liquid crystal display device is provided with the TFT substrate according to any one of the first to seventh aspects of the present invention that has a high pixel aperture ratio and excellent characteristics of the minimal potential change at the pixel electrodes. Therefore, it is possible to suppress the power consumption of the backlight and to prevent the occurrence of flickering, thereby achieving high quality display even with the low-frequency driving.

### Effects of the Invention

According to the present invention, the shielding electrode, which is formed in a different layer from the gate wiring lines and the source wiring lines, is extended along both wiring lines so as to lie between the two wiring lines and the pixel electrodes, and the shielding electrode is made of a transparent conductive material. This makes it possible to minimize potential changes at the pixel electrodes without reducing the aperture ratio of the pixels. Therefore, the power consumption of the backlight can be reduced, and an occurrence of flickering can be effectively prevented, thereby achieving high quality display even with the low-frequency driving. As a result, the reduction in power consumption is made possible while ensuring desired display quality.

### BRIEF DESCRIPTION OF THE DRAWINGS

FIG. 1 is a schematic plan view of a liquid crystal display device according to an embodiment.

FIG. 2 is a cross-sectional view showing a cross-sectional structure along the line II-II in FIG. 1.

FIG. 3 is a schematic plan view of a configuration of one pixel in a TFT substrate.

FIG. 4 is a cross-sectional view showing a cross-sectional structure along the line IV-IV in FIG. 3.

FIG. 5 is a cross-sectional view showing a cross-sectional structure along the line V-V in FIG. 3.

FIG. 6 shows a first half of a process of manufacturing a TFT substrate. FIG. 6(a) shows a state in which a gate insulating film has been formed; FIG. 6(b) shows a state in which a source electrode and a drain electrode have been formed; and FIG. 6(c) shows a state in which a first interlayer insulating film has been formed.

FIG. 7 shows a second half of the process of manufacturing a TFT substrate. FIG. 7(a) shows a state in which a shielding electrode has been formed; FIG. 7(b) shows a state in which a second interlayer insulating film has been formed; and FIG. 7(c) shows a state in which a contact hole has been formed in a multi-layer insulating film.

### DETAILED DESCRIPTION OF EMBODIMENTS

Below, an embodiment of the present invention will be explained in detail with reference to figures. The present invention is not limited to the embodiment described below.

### Embodiment of the Present Invention

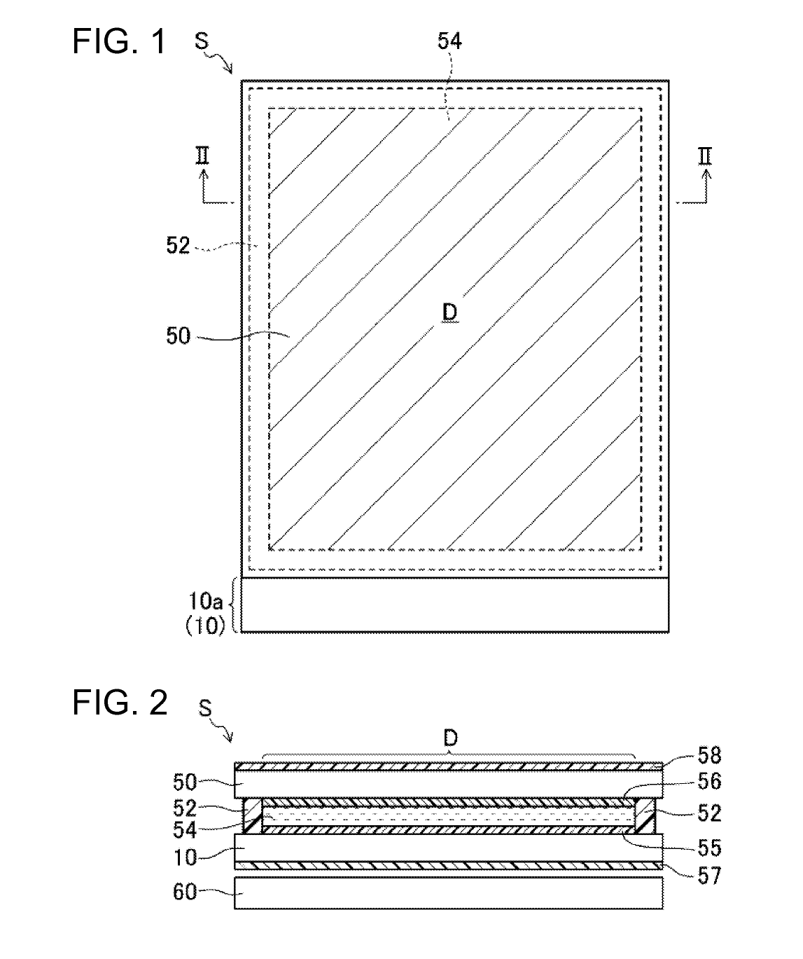

FIG. 1 is a schematic plan view of a liquid crystal display device S according to this embodiment. FIG. 2 is a schematic cross-sectional view showing a cross-sectional structure along the line II-II in FIG. 1. In FIG. 1, a polarizing plate 58 shown in FIG. 2 is not shown.

<Overall Configuration of Liquid Crystal Display Device S>

The liquid crystal display device S is a transmissive liquid crystal display device that includes a TFT substrate 10 and an opposite substrate 50 disposed to face each other, a frame-shaped sealing member 52 that bonds the TFT substrate 10 and the opposite substrate 50 to each other in the respective outer edge portions thereof, a liquid crystal layer 54 sealed inside the sealing member 52 between the TFT substrate 10 and the opposite substrate 50, and a backlight 60 disposed on the rear surface side of these components (lower side in FIG. 2).

This liquid crystal display device S has a display region D that performs image display and a terminal region 10a that is disposed outside of the display region D. The display region D is a region where the TFT substrate 10 and the opposite substrate 50 overlap inside the sealing member 52, i.e., a region where the liquid crystal layer 54 is formed. The terminal region 10a is a part of the TFT substrate 10 that protrudes beyond the opposite substrate 50.

The display region D is formed in a rectangular shape, for example, and includes a plurality of pixels arranged in a matrix. Each pixel is the smallest unit of an image. On the other hand, although not shown in figures, the terminal region 10a has gate wiring lines and source wiring lines, which will be described later, led out thereto, and the end portions thereof form terminals. These terminals of the respective wiring lines are connected to an integrated circuit chip, a wiring substrate, and the like that are mounted through anisotropic conductive films (referred to as ACFs below) or the like, thereby allowing display signals and the like from an external circuit to be supplied to the main body of the display device.

The TFT substrate 10 and the opposite substrate 50 are formed in a rectangular shape, for example. As shown in FIG. 2, alignment films 55 and 56 are respectively disposed on inside surfaces that face each other, and on respective outer surfaces, polarizing plates 57 and 58 are disposed. The liquid crystal layer 54 is made of a nematic liquid crystal material or the like that has electrooptic characteristics.

<Configuration of TFT Substrate 10>

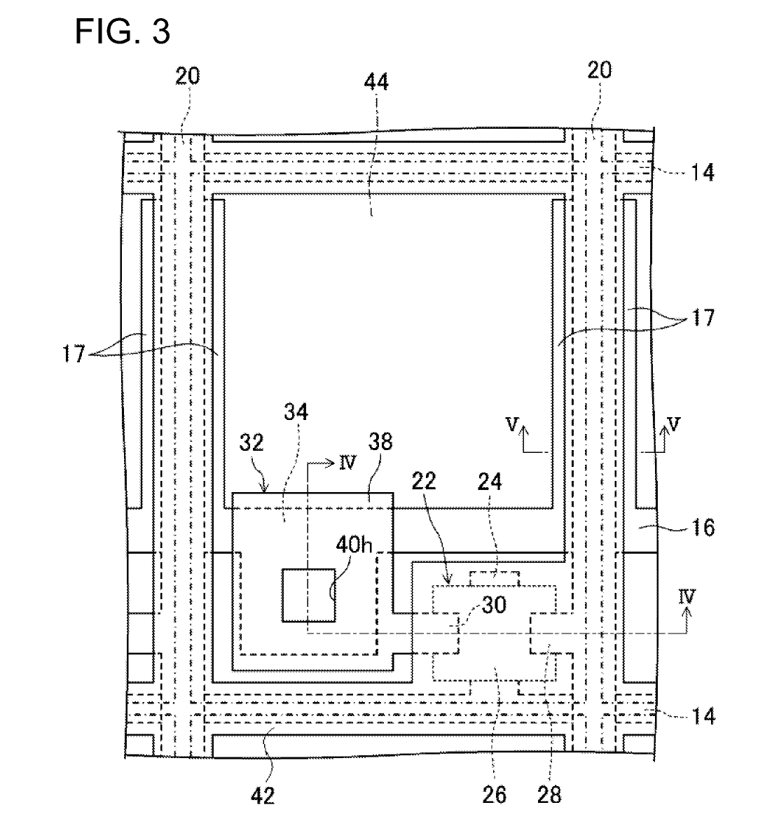

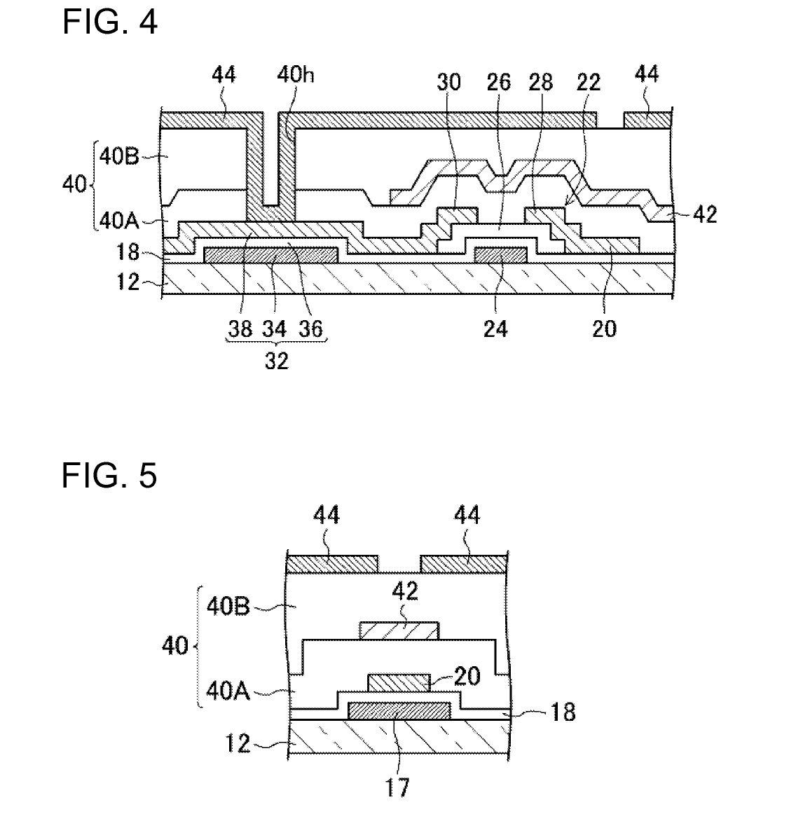

FIGS. 3 and 4 are diagrams showing a schematic configuration of the TFT substrate 10. FIG. 3 is a plan view showing a configuration of one pixel. FIG. 4 is a cross-sectional view showing a cross-sectional configuration along the line VI-VI in FIG. 3. FIG. 5 is a cross-sectional view along the line V-V in FIG. 3, showing a cross-sectional configuration.

As shown in FIGS. 4 and 5, the TFT substrate 10 has a transparent insulating substrate 12 such as a glass substrate or the like as a base substrate. In the display region D, as shown in FIG. 3, a plurality of gate wiring lines 14 that extend in parallel with each other, a plurality of storage capacitance wiring lines 16 that extend in parallel with each other along the respective gate wiring lines 14, a gate insulating film 18 (shown in FIGS. 4 and 5) that covers the respective gate wiring lines 14 and the respective storage capacitance wiring lines 16, and a plurality of source wiring lines 20 that extend in parallel with each other in a direction that orthogonal to the respective gate wiring lines 14 and the respective storage capacitance wiring lines 16 through the gate insulating film 18 are formed on the insulating substrate 12.

The gate wiring lines 14 and the source wiring lines 20 are formed in a grid shape as a whole so as to border the respective pixels, and the gate insulating film 18 is formed across substantially the entire surface of the substrate. The storage capacitance wiring lines 16 are provided for the respective gate wiring lines 14, and are extended over a plurality of pixels so as to run through those pixels, which are arranged in a direction in which the gate wiring lines 14 are extended.

The insulating substrate 12 also has light-shielding portions 17 formed thereon. The light-shielding portions 17 are made of portions of the storage capacitance wiring lines 16 that are extended to the side along the source wiring lines 20, and are therefore formed integrally with the storage capacitance wiring lines 16. The light-shielding portions 17 respectively overlap the source wiring lines 20 through the gate insulating film 18. These light-shielding portions 17 are formed to be wider than the source wiring lines 20, and prevent light from leaking through portions between the respective adjacent pixels.

Also, in the TFT substrate 10, for each of the intersections of the respective gate wiring lines 14 and the respective source wiring lines 20, i.e., in each pixel, a TFT 22, a storage capacitance element 32, and a pixel electrode (indicated with a one-dotted line in FIG. 3) 44 are provided.

As shown in FIG. 4, each TFT 22 has a bottom-gate structure, and includes a gate electrode 24 covered by the gate insulating film 18, a semiconductor layer 26 that is disposed on the gate insulating film 18 so as to overlap the gate electrode 24, and a source electrode 28 and a drain electrode 30 that are respectively connected to the semiconductor layer 26 and that are separated from each other.

The gate electrode 24 is formed of a protruding portion of the gate wiring line 14 that runs through the corresponding intersection. In FIG. 3, the protruding portion protrudes toward the upper side. The source electrode 28 is formed of a protruding portion of a source wiring line 20 that runs through the corresponding intersection. The protruding portion protrudes to the left side in FIG. 3, and is connected to the semiconductor layer 26 on the right side thereof in FIG. 3. On the other hand, the drain electrode 30 is connected to the left side of the semiconductor layer 26 in FIG. 3 so as to face the source electrode 28. The semiconductor layer 26 is an oxide semiconductor made of indium gallium zinc oxide (referred to as IGZO below), for example, which allows each TFT 22 to have excellent characteristics of high mobility, high reliability, and low OFF current.

In this embodiment, the semiconductor layer 26 of each TFT 22 is made of IGZO metal oxide, but the semiconductor layer 26 may also be made of another oxide semiconductor such as zinc oxide (ZiO), zinc tin oxide (ZTO), strontium titanate (SrTiO₂), indium oxide (In₂O₃), or copper aluminum oxide (CuAlO₂). The semiconductor layer 26 may be made of polysilicon or amorphous silicon, instead of an oxide semiconductor.

Each storage capacitance element 32 is provided with a lower electrode 34 that is made of a part of the storage capacitance wiring line 16 and that is covered by the gate insulating film 18, a dielectric layer 36 made of a portion of the gate insulating film 18 corresponding the lower electrode 34, and an upper electrode 38 that overlaps the lower electrode 34 through the dielectric layer 36. Between the lower electrode 34 and the upper electrode 38, a storage capacitance is formed in accordance with the permittivity of the dielectric layer 36.

The part of the storage capacitance wiring line 16 that forms the lower electrode 34 is expanded toward the gate wiring line 14 on the lower side of FIG. 3, thereby allowing the lower electrode 34 to have a prescribed area. On the other hand, the upper electrode 38 is made of a portion of the drain electrode 30 that is extended toward an area above the lower electrode 34, being integrally formed therewith. When the storage capacitance element 32 is configured in this manner, because the dielectric layer 36 of the storage capacitance element 32 is made of the gate insulating film 18 that is relatively thin, it is possible to achieve a desired capacitance with a smaller area as compared with the case in which the dielectric layer 36 is formed of a relatively thick insulating film, i.e., interlayer insulating films 40A and 40B, which will be later described. This makes it possible to improve the aperture ratio of each pixel.

As shown in FIG. 4, the respective TFTs 22 and the respective storage capacitance elements 32 are covered by a multi-layer insulating film 40 that is formed across substantially the entire surface of the substrate. On this multi-layer insulating film 40, the respective pixel electrodes 44 are formed.

As shown in FIGS. 3 and 4, at a location that corresponds to each upper electrode 38, a contact hole 40h is formed through the multi-layer insulating film 40 so as to reach the upper electrode 38, and through this contact hole 40h, each pixel electrode 44 is connected to the upper electrode 38. Each pixel electrode 44 covers the TFT 22 and the storage capacitance element 32 through the multi-layer insulating film 40, and is formed to have a large area that corresponds to the entire pixel such that outer edges thereof overlap the gate wiring lines 14 and the source wiring lines 20 through the multi-layer insulating film 40, respectively. This makes it possible to apply a voltage to the liquid crystal layer 54 in a region where the TFT 22 and the storage capacitance element 32 are formed in each pixel, as described later, and therefore, transmittance of light that passes through areas in and around the TFT 22 and the storage capacitance element 32 can also be adjusted. As a result, the region where the TFT 22 and the storage capacitance element 32 are formed can also be utilized for display.

The multi-layer insulating film 40 is formed of a first interlayer insulating film 40A and a second interlayer insulating film 40B that are respectively made of organic insulating films such as an acrylic resin, for example, and that are laminated in this order. Between these first interlayer insulating film 40A and second interlayer insulating film 40B, a shielding electrode 42 is formed.

The shielding electrode 42 is extended along the respective gate wiring lines 14 and the respective source wiring lines 20 so as to form a grid pattern that has openings, each of which corresponds to substantially the entire area of a pixel. The shielding electrode 42 is disposed between the respective gate wiring lines 14 or the respective source wiring lines 20 and the respective pixel electrodes 44. More specifically, as shown in FIG. 3, the shielding electrode 42 is formed to be wider than the respective gate wiring lines 14 and source wiring lines 20 so as to entirely overlap the respective gate wiring lines 14 and the respective source wiring lines 20 in the width direction. The shielding electrode 42 is formed so as to overlap the outer edges of each pixel electrode 44 through the second interlayer insulating film 40B of the upper layer as shown in FIG. 5, while covering each TFT 22 through the first interlayer insulating film 40A of the lower layer as shown in FIG. 4. This shielding electrode 42 is made of indium tin oxide (referred to as ITO below) that is transparent.

The shielding electrode 42 is extended along the respective wiring lines 14 and 20 to the outside of the display region D, and although not shown in figures, led-out wiring lines are extended out from four corners of the electrode 42, for example, to the terminal region, and the end portions thereof form terminals. By receiving a fixed potential sent to the terminals through a wiring substrate or the like, the shielding electrode 42 serves as an electric shield for electric field effects generated as a result of a potential difference between the respective gate wiring lines 14 or the respective source wiring lines 20 and the respective pixel electrodes 44.

This shielding electrode 42 also serves as a protective film of the respective TFTs 22, and prevents moisture, oxygen, and the like from entering the TFTs 22 from the outside, which makes it possible to suppress the degradation of performance of the TFTs 22. When the interlayer insulating films 40A and 40B are made of organic insulating films, it is possible to make it easier to form thick films and to achieve a higher degree of flatness, as compared with the case of forming the interlayer insulating films 40A and 40B of inorganic insulating films. As a result, the pixel electrodes 44 formed on the multi-layer insulating film 40 can be appropriately planarized, and therefore, the thickness of the liquid crystal layer 54 is made even throughout the respective pixels. This results in an improvement in the display quality of the liquid crystal display device S. Such interlayer insulating films 40A and 40B made of organic insulating films tend to allow electric current to flow at high temperatures. Therefore, depending on the usage environment, the insulating property thereof may not be maintained, and a small leak current may flow therein. However, because of the shielding electrode 42, a transfer of electric charges to the upper part of each TFT 22, which is caused by the leak current, can be blocked. This prevents a reliability problem caused by a change in the TFT characteristics that occurs as a result of accumulation of electric charges in the upper part of each TFT 22, thus providing the TFTs 22 with excellent characteristics.

In this embodiment, the shielding electrode 42 is made of ITO, but the shielding electrode 42 may be formed of another transparent conductive material such as indium zinc oxide (referred to as IZO below).

<Configuration of Opposite Substrate 50>

Although not shown in figures, the opposite substrate 50 includes, on a transparent insulating substrate such as a glass substrate provided as a base substrate, a black matrix formed in a grid pattern so as to correspond to the gate wiring lines 14 and the source wiring lines 20, color filters of a plurality of colors that include red layers, green layers, and blue layers formed in the respective grids of the black matrix in a certain arrangement pattern, a common electrode formed so as to cover the black matrix and the respective color filters, and photospacers that are formed on the common electrode in a columnar shape.

<Configuration of Backlight 60>

Although not shown in figures, the backlight 60 includes a light source such as an LED (Light Emitting Diode) or a cold cathode fluorescent lamp, a light guide plate, and a plurality of optical sheets including a prism sheet. Light that entered the light guide plate from the light source is emitted as even planar light from an emitting surface of the light guide plate through the respective optical sheets toward the panel that is constituted of the TFT substrate 10 and the opposite substrate 50 bonded to each other.

<Operation of Liquid Crystal Display Device S>

In the liquid crystal display device S having the above-mentioned configuration, in each pixel, when a gate signal is sent to the gate electrode 24 through the gate wiring line 14, thereby turning the TFT 22 on, a source signal is sent to the source electrode 28 through the source wiring line 20, and through the semiconductor layer 26 and the drain electrode 30, a prescribed potential is written into the pixel electrode 44, and the storage capacitance element 32 is charged. This causes a potential difference to be created between each pixel electrode 44 in the TFT substrate 10 and the common electrode in the opposite substrate 50, and as a result, a prescribed voltage is applied to the liquid crystal layer 54. When the TFT 22 is in the OFF state, the storage capacitance formed in the storage capacitance element 32 maintains the level of the voltage that was written in the corresponding pixel electrode 44. In the liquid crystal display device S, by applying different voltages to the liquid crystal layer 54 and thereby changing the orientation state of the liquid crystal molecules, the transmittance of light emitted from the backlight 60 and passing through the liquid crystal layer 54 is adjusted in each pixel. This way, images are displayed.

In this liquid crystal display device S, image display is performed by low-frequency driving in which the gate wiring lines 14 and the source wiring lines 20 are driven by AC voltage, and the potentials that are respectively written into the plurality of pixel electrodes 44 through the source wiring lines 20 are refreshed at a frequency of 60 Hz or lower. Also, in order to reduce the power consumption, the common electrode in the opposite substrate 50 is also provided with AC voltage that reverses direction in a substantially synchronized manner with the AC voltage that is supplied to the source wiring lines 20. In the case of the normally-white mode, for example, the AC voltage supplied to the common electrode is set to have the same amplitude as that of the AC voltage supplied to the source wiring lines 20, and in the black display, the source wiring lines 20 are provided with a voltage that has an opposite phase to that of the AC voltage of the common electrode. In the white display, the source wiring lines 20 are provided with a voltage that has the same phase as that of the AC voltage supplied to the common electrode. In such AC driving, in each pixel, a potential at the pixel electrode 44 is superimposed with a potential change at the common electrode, and the resultant potential difference is a voltage that drives the liquid crystal layer 54. As a result, the amplitude of the AC voltage supplied to the source wiring lines 20 can be made small, making possible a reduction in power consumption of the liquid crystal display device S. Also, by providing the common electrode with AC voltage in the manner described above, the storage capacitance wiring lines 16 are also provided with AC voltage that has the same phase and the same amplitude as those of the voltage at the common electrode. This way, during the OFF period of the TFT 22, the potential at the lower electrode 34 of the storage capacitance element 32 changes to have the same phase and the same amplitude as those of the AC voltage at the common electrode. As a result, the potential that was written into the pixel electrode 44 during the ON period of the TFT 22 can be maintained in a desired manner until the next writing operation.

—Manufacturing Method—

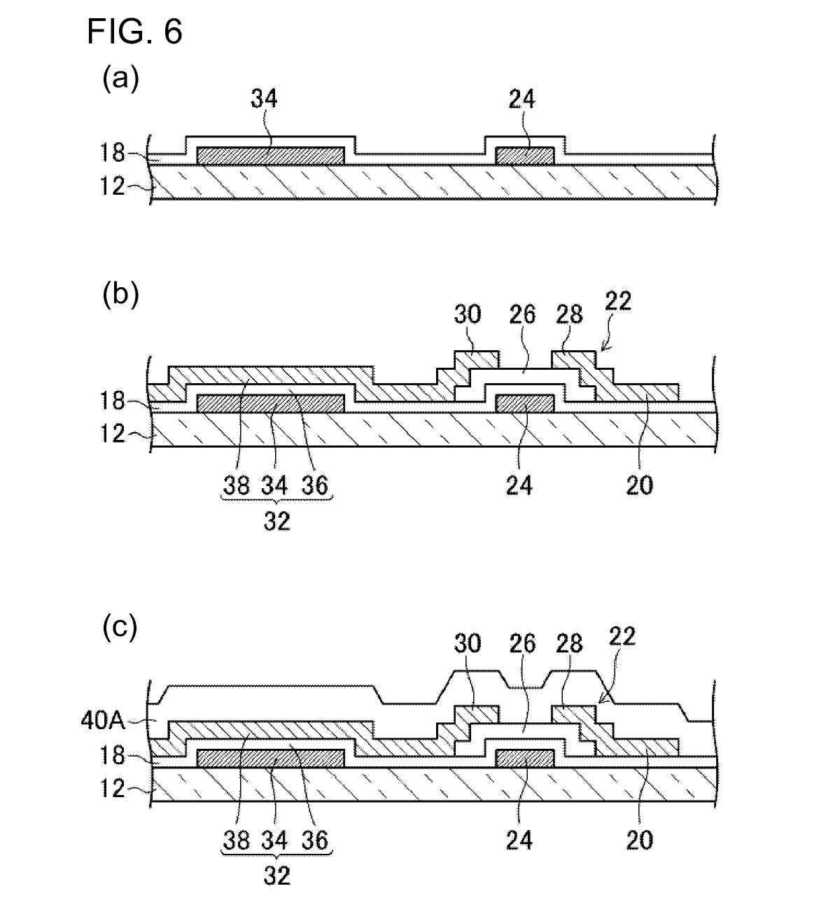

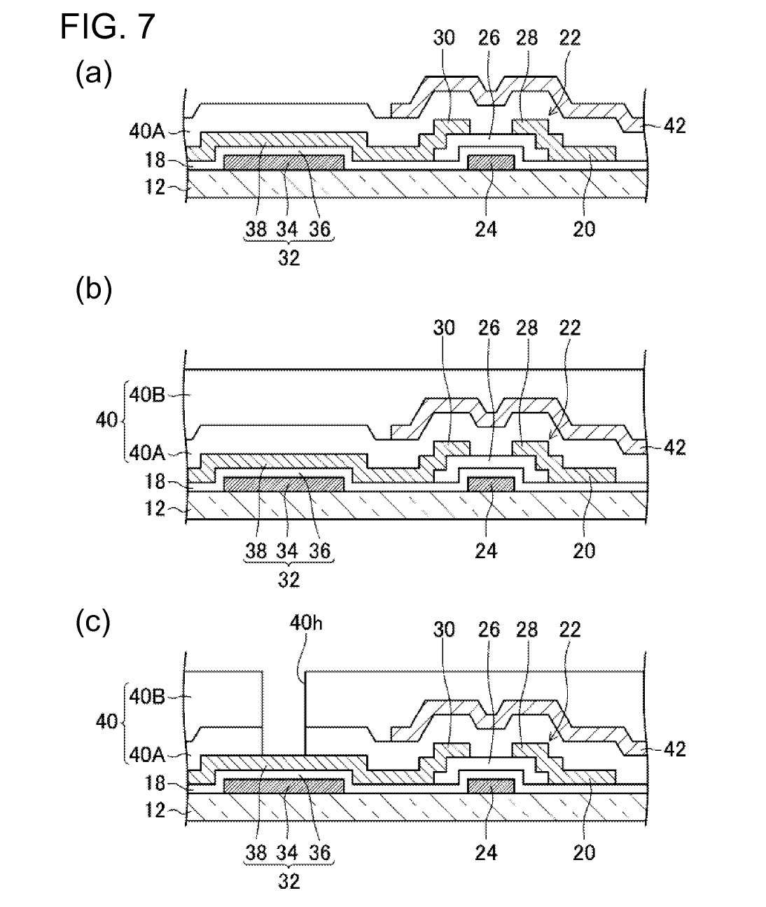

Next, an example of a method of manufacturing the liquid crystal display device S and the TFT substrate 10 will be explained with reference to FIGS. 6 and 7. FIG. 6 shows the first half of the process of manufacturing the TFT substrate 10, and FIG. 7 shows the second half of the process of manufacturing the TFT substrate 10. In FIGS. 6 and 7, each diagram shows a cross section that corresponds to that shown in FIG. 4.

The method of manufacturing the liquid crystal display device S of this embodiment includes a TFT substrate manufacturing process, an opposite substrate manufacturing process, a bonding process, and a mounting process.

<TFT Substrate Manufacturing Process>

First, on the insulating substrate 12 such as a glass substrate that has been prepared in advance, a metal multi-layer film is formed by laminating a titanium film, an aluminum film, and a titanium film in this order by sputtering, for example. Thereafter, by patterning this metal multi-layer film by photolithography, the gate wiring lines 14, the gate electrodes 24, the storage capacitance wiring lines 16, the lower electrodes 34, and the light-shielding portions 17 are simultaneously formed. Next, on the substrate having the gate wiring lines 14, the storage capacitance wiring lines 16, and the like formed thereon, a silicon nitride film is formed by the plasma CVD (Chemical Vapor Deposition) method, thereby forming the gate insulating film 18 as shown in FIG. 6(a).

Next, on the substrate having the gate insulating film 18 formed thereon, an IGZO oxide semiconductor film is formed by sputtering, and then by patterning this oxide semiconductor film by photolithography, the semiconductor layer 26 is formed. Thereafter, on the substrate having the semiconductor layer 26 formed thereon, a titanium film, an aluminum film, and a titanium film, for example, are formed in this order by sputtering, thereby forming a metal multi-layer film. This metal multi-layer film is patterned by photolithography to simultaneously form the source wiring lines 20, the source electrodes 28, the drain electrodes 30, and the upper electrodes 38 as shown in FIG. 6(b).

Next, the substrate having the source wiring lines 20, the drain electrodes 30, and the like formed thereon is coated with an organic insulating material such as an acrylic resin, for example, by a spin coating method, a slit coating method, or the like. Thereafter, the coating film is baked and dried, thereby forming the first interlayer insulating film 40A as shown in FIG. 6(c).

Next, on the substrate having the first interlayer insulating film 40A formed thereon, an ITO film is formed by sputtering, and by patterning this ITO film by photolithography, the shielding electrode 42 is formed as shown in FIG. 7(a).

Next, the substrate having the shielding electrode 42 formed thereon is coated with an organic insulating material such as an acrylic resin, for example, by a spin coating method, a slit coating method, or the like. Then, by baking and drying the coating film, the second interlayer insulating film 40B is formed as shown in FIG. 7(b), thereby completing the multi-layer insulating film 40.

Thereafter, the multi-layer insulating film (the first interlayer insulating film 40A and the second interlayer insulating film 40B) 40 is patterned by photolithography, thereby forming contact holes 40h in the multi-layer insulating film 40 as shown in FIG. 7(c). On this multi-layer insulating film 40, an ITO film is formed by sputtering, and by patterning the ITO film by photolithography, the pixel electrodes 44 are formed.

The TFT substrate 10 can be manufactured in the above-mentioned manner.

<Opposite Substrate Manufacturing Process>

First, by a spin coating method or a slit coating method, the entire surface of an insulating substrate such as a glass substrate is coated with a negative-type acrylic photosensitive resin that includes particles such as carbon dispersed therein. Thereafter, the photosensitive resin coating film is patterned by performing an exposure process using a photomask and a development process, thereby forming a black matrix.

Next, the substrate having the black matrix formed thereon is coated with a negative-type acrylic photosensitive resin that is colored in red, green, or blue, for example. Thereafter, the photosensitive resin coating film is patterned by performing an exposure process using a photomask and a development process, thereby forming colored layers of a selected color (red layers, for example). Thereafter, by performing a similar process repeatedly, colored layers of other two colors (green layers and blue layers, for example) are formed, thereby forming color filters.

Next, on the substrate having the color filters formed thereon, an ITO film is formed by sputtering, for example, thereby forming the common electrode. Thereafter, the substrate having the common electrode formed thereon is coated with a positive-type phenolic novolak photosensitive resin by a spin coating method. Thereafter, the photosensitive resin coating film is patterned by performing an exposure process using a photomask and a development process, thereby forming photospacers.

The opposite substrate 50 can be manufactured in the manner described above.

<Bonding Process>

First, the surface of the TFT substrate 10 is coated with a low-temperature curing polyimide resin by a printing method, and thereafter, the coating film undergoes a baking process and a rubbing process, thereby forming an alignment film 55. Also, the surface of the opposite substrate 50 is coated with a similar polyimide resin by a printing method, and thereafter, the coating film undergoes a baking process and a rubbing process, thereby forming an alignment film 56.

Next, on the opposite substrate 50 having the alignment film 56 formed thereon, a sealing member 52 is formed in a rectangular frame shape by using a dispenser or the like. The sealing member 52 is made of a material such as a UV curable/thermosetting resin. Thereafter, a prescribed amount of liquid crystal material is dropped onto a region inside the sealing member 52 on the opposite substrate 50 having the sealing member 52 formed thereon.

Next, the opposite substrate 50 having the liquid crystal material dropped thereon and the TFT substrate 10 having the alignment film 55 are assembled under a reduced pressure, and then, the stacked substrates are placed in the atmosphere pressure so as to apply a pressure onto the surfaces of the stacked substrates. After the sealing member 52 in the stacked substrates is irradiated with UV (Ultraviolet) light for temporary-curing, the stacked substrates are heated, thereby permanently curing the sealing member 52. This way, the TFT substrate 10 and the opposite substrate 50 are bonded to each other.

Next, the polarizing plates 57 and 58 are attached to the respective outer surfaces of the TFT substrate 10 and the opposite substrate 50 that have been bonded to each other.

<Mounting Process>

After the polarizing plates 57 and 58 are attached on the respective surfaces of the bonded substrates, ACFs are disposed on the terminal region 10a, to which an integrated circuit chip and a wiring substrate are thermal-bonded through the ACFs. This way, the integrated circuit chip and the wiring substrate are mounted onto the bonded substrates. Thereafter, the backlight 60 that has been prepared in advance is attached to the rear surface of the bonded substrates having the integrated circuit chip and the wiring substrate mounted thereon.

The liquid crystal display device S can be manufactured in the manner described above.

### Effects of Embodiment

According to this embodiment, the shielding electrode 42 is disposed between the respective gate wiring lines 14 or the respective source wiring lines 20 and the respective pixel electrodes 44. Therefore, electric field effects generated as a result of a potential difference between the respective gate wiring lines 14 or the respective source wiring lines 20 and the respective pixel electrodes 44 are electrically shielded by the shielding electrode 42, making it possible to reduce or eliminate a parasitic capacitance formed therebetween. That is, not only the parasitic capacitance between the pixel electrodes 44 and the source wiring lines 20, but also the parasitic capacitance between the pixel electrodes 44 and the gate wiring lines 14 can be reduced or eliminated.

The shielding electrode 42 is formed so as to entirely cover the respective gate wiring lines 14 and the respective source wiring lines 20, and therefore, it is possible to reduce or prevent a parasitic capacitance formed between these wiring lines 14 and 20 and the respective pixel electrodes 44 as a result of fringe fields.

Further, because the semiconductor layer of each TFT is made of IGZO oxide semiconductor, the OFF current of each TFT can be reduced. Also, the potential at the pixel electrode during the OFF period of the TFT 22 can also be maintained by a storage capacitance that is formed between the shielding electrode 42 and an outer edge of the pixel electrode 44 that overlaps the shielding electrode 42, in addition to the storage capacitance element 32. This makes it possible to minimize the potential change at the pixel electrode 44.

The shielding electrode 42 is made of an ITO that is transparent, and therefore, even though it is formed in the respective pixels, the aperture ratio is not reduced. Also, because the shielding electrode 42 has openings, each of which corresponds to substantially the entire area of each pixel, the light transmittance is not lowered almost at all.

Thus, the power consumption of the backlight 60 can be reduced, and it is possible to perform the high quality display while effectively preventing the occurrence of flickering even with the low-frequency driving. As a result, the reduction in power consumption can be made possible while ensuring a desired display quality.

An embodiment of the present invention has been described above, but the technical scope of the present invention is not limited to the scope of the description of the embodiment described above. The above embodiment is an example, and it shall be understood by those skilled in the art that the combinations of the respective constituting elements and the respective processes can be modified in various manners, and that such modifications are also included in the scope of the present invention.

For example, in the above embodiment, the multi-layer insulating film 40 is made of two interlayer insulating films, which are the first interlayer insulating film 40A and the second interlayer insulating film 40B respectively made of organic insulating films, but the present invention is not limited to this. That is, the first interlayer insulating film 40A and the second interlayer insulating film 40B may be respectively made of multi-layer films that are formed by appropriately combining an inorganic insulating film such as silicon nitride (SiN) or silicon oxide (SiO) and an organic insulating film. The inorganic insulating film is formed by the LP (Low Pressure) CVD method, plasma CVD method, sputtering, or the like, for example.

When the second interlayer insulating film 40B is made of an inorganic insulating film and an organic insulating film, it is preferable that the organic insulating film be formed on the inorganic insulating film. With such a lamination structure, the uppermost layer of the multi-layer insulating film 40 is made of the organic insulating film, and therefore, the pixel electrodes 44 formed on the multi-layer insulating film 40 are appropriately planarized, allowing the thickness of the liquid crystal layer 54 to be even throughout the respective pixels. As a result, the display quality of the liquid crystal display device S is improved.

Alternatively, the first interlayer insulating film 40A and the second interlayer insulating film 40B may be respectively formed of the inorganic insulating film only. Also, the multi-layer insulating film 40 may include another insulating film, in addition to the first interlayer insulating film 40A and the second interlayer insulating film 40B. That is, the multi-layer insulating film 40 may be formed of three or more layers of insulating films.

In the above embodiment, each TFT 22 has a bottom-gate structure, but the TFT 22 may have a top-gate structure in which the positions of the gate electrode 24 and the semiconductor layer 26 are reversed over the gate insulating film 18. In the top-gate structure, for example, a semiconductor layer is formed on an insulating substrate; a gate electrode is disposed above the semiconductor layer through a gate insulating film; a source electrode and a drain electrode are formed so as to be separated from each other on an interlayer insulating film that covers the gate electrode; and the source electrode and the drain electrode are respectively connected to the semiconductor layer through contact holes that are formed in the interlayer insulating film and the gate insulating film.

In the above embodiment, the transmissive liquid crystal display device S was described as an example. However, the present invention is not limited to this, and can be applied to transflective and reflective liquid crystal display devices. Also, the present invention can be applied to other display devices such as an organic EL (Electroluminescence) display device and a plasma display device.

### INDUSTRIAL APPLICABILITY

As described above, the present invention is useful for a TFT substrate and a liquid crystal display device equipped with the same, and particularly, the present invention can be suitably used for a TFT substrate that needs to minimize potential changes at pixel electrodes without reducing the aperture ratio of the pixels and for a liquid crystal display device equipped with the same.

### DESCRIPTIONS OF REFERENCE CHARACTERS

S liquid crystal display device
10 TFT substrate (thin film transistor substrate)
14 gate wiring line
16 storage capacitance wiring line
18 gate insulating film
20 source wiring line
22 TFT (thin film transistor)
24 gate electrode
26 semiconductor layer
28 source electrode
30 drain electrode
32 storage capacitance element
34 lower electrode
36 dielectric layer
38 upper electrode
40 multi-layer insulating film
40A first interlayer insulating film
40B second interlayer insulating film
42 shielding electrode
44 pixel electrode
50 opposite substrate
54 liquid crystal layer

1. A thin film transistor substrate, comprising:
a plurality of gate wiring lines that extend in parallel with each other;
a plurality of source wiring lines that extend in parallel with each other so as to intersect with the respective gate wiring lines; and
a thin film transistor and a pixel electrode that are provided for each of intersections of the respective gate wiring lines and the respective source wiring lines,
wherein a plurality of pixels, each of which includes the thin film transistor and the pixel electrode, are defined by the respective gate wiring lines and the respective source wiring lines,
wherein, in each of the pixels, the thin film transistor comprises: a gate electrode; a semiconductor layer; a source electrode; and a drain electrode, the gate electrode being connected to one of the gate wiring lines, which runs through a corresponding intersection, the semiconductor layer overlapping the gate electrode through a gate insulating film, the source electrode being connected to one side of the semiconductor layer and being connected to one of the source wiring lines, which runs through the corresponding intersection, the drain electrode being connected to another side of the semiconductor layer so as to face the source electrode and being connected to the pixel electrode, and
wherein the thin film transistor substrate further comprises: a multi-layer insulating film that includes two layers of interlayer insulating films laminated to each other and that covers the respective gate wiring lines and the respective source wiring lines, the multi-layer insulating film having the respective pixel electrodes formed thereon; and
a shielding electrode that is disposed between the two layers of interlayer insulating films and that is extended along the respective gate wiring lines and the source wiring lines so as to lie between the respective gate wiring lines or the respective source wiring lines and the respective pixel electrodes, the shielding electrode being made of a transparent conductive material.

2. The thin film transistor substrate according to claim 1,
wherein the shielding electrode is formed wider than the respective gate wiring lines and the respective source wiring lines so as to entirely overlap the respective gate wiring lines and the respective source wiring lines in a width direction thereof.

3. The thin film transistor substrate according to claim 1,
wherein the shielding electrode is formed so as to overlap an outer edge of each of the pixel electrodes through the interlayer insulating film of an upper layer.

4. The thin film transistor substrate according to claim 1,
wherein the shielding electrode is formed so as to cover the respective thin film transistors.

5. The thin film transistor substrate according to claim 1,
wherein, of the two layers of interlayer insulating films, at least the interlayer insulating film of the upper layer is made of an organic insulating film or made of a multi-layer film formed by laminating an inorganic insulating film and an organic insulating film in this order.

6. The thin film transistor substrate according to claim 1,
wherein the semiconductor layer of each of the thin film transistors is made of an oxide semiconductor.

7. The thin film transistor substrate according to claim 1,
wherein each of the thin film transistors has a bottom-gate structure in which the gate electrode is covered by the gate insulating film, and the semiconductor layer, the source electrode, and the drain electrode are formed on the gate insulating film,
wherein the thin film transistor substrate further comprises: storage capacitance wiring lines that are provided for the respective gate wiring lines, the storage capacitance wiring lines being extended in parallel with each other along the respective gate wiring lines; and storage capacitance elements provided for the respective pixels, and
wherein, in each of the pixels, the storage capacitance element comprises: a lower electrode that is connected to the storage capacitance wiring line and that is covered by the gate insulating film; a dielectric layer that is made of a portion of the gate insulating film corresponding to the lower electrode; and an upper electrode that overlaps the lower electrode through the dielectric layer.

8. A liquid crystal display device, comprising:
the thin film transistor substrate according to claim 1;
an opposite substrate disposed to face the thin film transistor substrate; and
a liquid crystal layer disposed between the thin film transistor substrate and the opposite substrate.
